(19) United States
(12) Patent Application Publication
(10) Pub. No.: US 2026/0052653 A1
(43) Pub. Date: Feb. 19, 2026

(54) INTERFACE MODULE WITH CORRUGATED THERMAL COUPLING MEMBER

(71) Applicant: Telefonaktiebolaget LM Ericsson (publ), Stockholm (SE)

(72) Inventors: Claudio D'INCÀ, Genova (IT); Sergio MOSTI, Genova (IT)

(21) Appl. No.: 19/102,387

(22) PCT Filed: Aug. 8, 2023
(86) PCT No.: PCT/EP2023/071917

§ 371 Date: Feb. 8, 2025

Related U.S. Application Data
(60) Provisional application No. 63/395,950, filed on Aug. 8, 2022.

(51) Int. Cl. H05K 7/20; G02B 6/42

(52) U.S. Cl. CPC H05K 7/20436; G02B 6/4261; G02B 6/4269

(57) ABSTRACT

An interface module according to some embodiments includes a cage, such as a small form factor pluggable (SFP) cage, configured to guide a signal connector towards an interface for connection with the signal connector. The cage includes a first side, an opening in the first side of the cage, and a corrugated thermal coupling member attached to the cage and extending across the opening in the first side of the cage. The corrugated thermal coupling member includes a plurality of alternating ridges and valleys that alternatingly extend above and below the first side.

### TECHNICAL FIELD

The present disclosure relates to an interface module having a coupling device configured for the thermal management of components, such as electrical or optical connectors and transceivers.

### BACKGROUND

In Radio Access nodes, optical transceiver modules are becoming more power demanding, for example, in order to provide for an increase of the bitrate and additional requested functions. Especially in very dense optical units, a special care must be taken to manage the thermal design for the heat dissipation in order to provide the requested node capacity bandwidth, in terms of number of transceivers located on the front face with respect to the unit space occupation inside a rack.

Currently, 10G Small Form Factor Pluggable (SFP) Dense Wavelength Division Multiplexer (DWDM) transceivers show a power consumption of 1.5 W. A current solution at 10G for a Fronthaul telecoms equipment located in one rack unit (44.45 mm thickness) is able to thermally manage the maximum possible number of front optical transceivers. A next generation DWDM SFP28 may show a power consumption of 2.5 W, and the power consumption can increase further if the SFP28 includes a full tunable laser or other functions, such as wavelength auto-negotiation. At the same time, the rack space available, such as 1 rack unit (1RU) in a “pizza box” format, should be able to host the maximum number of front interfaces (e.g. more than 42), in order to optimize space occupied inside the rack. It is useful to utilize the full space available on the front of the unit to place a maximum number of optical transceivers. In order to manage components with high heat outputs, a new and efficient way of thermal management would be advantageous.

One issue that has arisen in the development of such connector systems is the build-up of heat in and around the connector. This problem is particularly pronounced for active cable assemblies (i.e., connectors or cables having embedded circuitry to boost their performance or carry out additional functions). To address this problem, heat sinks have been used to dissipate the heat that builds up in the connector.

### SUMMARY

An interface module according to some embodiments includes a cage, e.g. a small form factor pluggable (SFP) cage, configured to guide a signal connector towards an interface for connection with the signal connector. The cage includes a first side, an opening in the first side of the cage, and a corrugated thermal coupling member attached to the cage and extending across the opening in the first side of the cage. The corrugated thermal coupling member includes a plurality of alternating ridges and valleys, and optionally, that alternatingly extend above and below the first side.

In some embodiments, the cage has an interior volume defined by the first side, a second side opposite the first side, and sidewalls extending between the first side and the second side, and the corrugated thermal coupling member alternatingly extends into and out of the interior volume.

The cage may be configured to guide the signal connector along a longitudinal direction when the signal connector is inserted into the cage, and the plurality of ridges and valleys of the corrugated thermal coupling member may extend in a transverse direction that is perpendicular to the longitudinal direction.

In some embodiments, an outer side of the plurality of ridges is configured to contact a main unit heat sink when the main unit heat sink is affixed to the interface module.

The corrugated thermal coupling member may be configured be deformed by contact with the main unit heat sink when the main unit heat sink is affixed to the interface module.

In some embodiments, an outer side of the plurality of ridges is configured to contact a printed circuit board (PCB) when the interface module is affixed to the PCB.

In some embodiments, the corrugated thermal coupling member is configured be deformed by contact with the PCB when the interface module is affixed to the PCB.

The cage may include a second side configured to be affixed to a main unit heat sink and a third side, opposite the second side, configured to be affixed to a PCB. The first side may include a sidewall that extends between the second side and the third side.

In some embodiments, an inner side of the plurality of valleys is configured to contact the signal connector when the signal connector is inserted into the cage. The corrugated thermal coupling member may be configured to provide a spring bias against the signal connector when the signal connector is inserted into the cage.

The interface module may further include a PCB and a main unit heat sink. The cage may be mounted to the PCB on a second side of the cage opposite the first side of the cage, and the main unit heat sink may be directly in contact with the first side of the cage.

The corrugated thermal coupling member may at least partially protrude into an internal volume of the cage before the signal connector is inserted into the cage and be pushed outward from the internal volume of the cage when the signal connector is inserted into the cage.

In some embodiments, the signal connector includes an optical connector, an electrical connector, and/or or an electro-optic connector. The signal connector may include an connector. The cage may be an optical transceiver cage, such as an SFP cage.

In some embodiments, the ridges and valleys are arranged at an angle that is oblique to a direction in which the signal connector is inserted in to the cage.

Some embodiments provide a dense wavelength division multiplexer including an interface module as described above.

A cage set for an interface module according to some embodiments includes a cage configured to guide a signal connector towards an interface for connection with the signal connector. The cage includes a first side, an opening in the first side, and a corrugated thermal coupling member attached to the cage and extending across the opening. The corrugated thermal coupling member includes a plurality of alternating ridges and valleys that alternatingly extend above and below the first side.

The cage may have an interior volume defined by the first side, a second side opposite the first side, and sidewalls extending between the first side and the second side, and the corrugated thermal coupling member may alternatingly extend into and out of the interior volume.

In some embodiments, the cage is configured to guide the signal connector along a longitudinal direction when the signal connector is inserted into the cage, and the plurality of ridges and valleys of the corrugated thermal coupling member extend in a transverse direction that is perpendicular to the longitudinal direction.

In some embodiments, an outer side of the plurality of ridges is configured to contact a main unit heat sink when the main unit heat sink is affixed to the interface module.

In some embodiments, the corrugated thermal coupling member is configured be deformed by contact with the main unit heat sink when the main unit heat sink is affixed to the interface module.

In some embodiments, an outer side of the plurality of ridges is configured to contact a PCB when the interface module is affixed to the PCB.

In some embodiments, the corrugated thermal coupling member is configured be deformed by contact with the PCB when the interface module is affixed to the PCB.

In some embodiments, the cage includes a second side configured to be affixed to a main unit heat sink and a third side, opposite the second side, configured to be affixed to a PCB and the first side includes a sidewall that extends between the second side and the third side.

In some embodiments, an inner side of the plurality of valleys is configured to contact the signal connector when the signal connector is inserted into the cage.

In some embodiments, the corrugated thermal coupling member is configured to provide a spring bias against the signal connector when the signal connector is inserted into the cage.

Some embodiments provide a dense wavelength division multiplexer including an cage set as described above.

In some embodiments, the corrugated thermal coupling member is attached to the cage at an edge of the opening in the first side of the cage near a first end of the cage at which the signal connector is inserted.

In some embodiments, the ridges and valleys are arranged at an angle that is oblique to a direction in which the signal connector is inserted in to the cage.

### BRIEF DESCRIPTION OF THE DRAWINGS

For a better understanding of examples of the present invention, and to show more clearly how the examples may be carried into effect, reference will now be made, by way of example only, to the following drawings in which:

FIG. 1A is a drawing of a part of a conventional interface module;

FIG. 1B is a cutaway illustration of a main unit including a conventional interface module;

FIG. 2 is a schematic diagram of a conventional arrangement of an interface module, a PCB and a heat sink;

FIG. 3 is an upper perspective view of an interface module according to some embodiments;

FIG. 4 is a lower perspective view of an interface module according to some embodiments;

FIG. 5 is an upper perspective cutaway view of one cage of an interface module according to some embodiments;

FIG. 6 is an upper perspective cutaway view of one cage of an interface module according to some embodiments that is mounted on a PCB;

FIGS. 7 and 8 illustrate an interface module according to some embodiments that is mounted to a PCB and on which a main unit heat sink is attached;

FIG. 9 is a schematic diagram of an arrangement of an SFP cage of an interface module according to some embodiments mounted to a PCB and a heat sink; and

FIG. 10 is a comparison structure showing the heat sink fins of a main unit heat sink structure according to some embodiments next to conventional heat sink fins of a main unit heat sink of a conventional structure.

FIG. 11 is a plan view of a SFP cage according to some embodiments.

### DETAILED DESCRIPTION

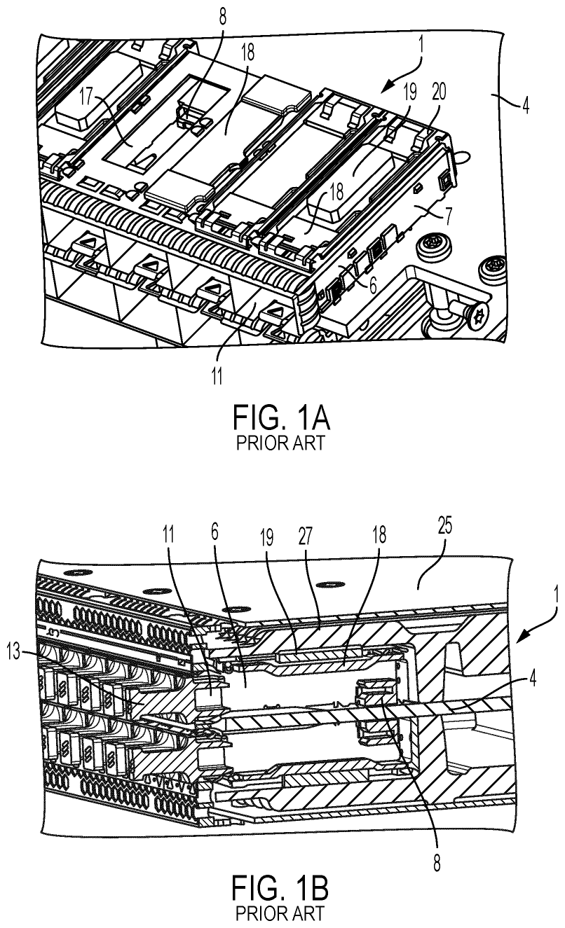

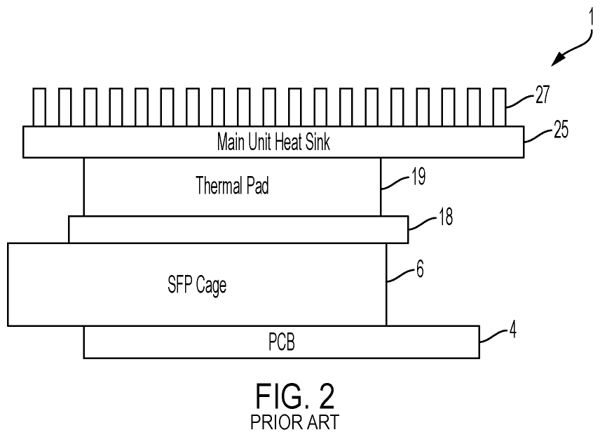

FIGS. 1A and 1B show a conventional interface module 1, comprising a plurality of cages 6. In FIG. 1A, the interface module 1 is mounted on a printed circuit board (PCB) 4. In FIG. 1B, a main unit assembly including a pair of interface modules 1 (shown in partial cutaway) are mounted on a PCB 4, and heat sinks 25 including heat sink fins 27 are attached to the interface modules 1.

Referring to FIGS. 1A and 1B, the cages 6 have an opening 11 at a front end, a rear face at an end that is opposite to the opening, and a cage body 7 extending between the opening 11 and the rear face. An interface 8 is positioned within the cage, towards, adjacent or at the rear face of the cage. The interface 8 provides a connection to electronic circuitry, e.g. on a base or PCB 4. The interface 8 may possess a shape and structure that is complementary to a corresponding shape and structure of a connector (not shown).

The cage 6 is configured to receive a connector (e.g. a connector for a cable assembly, for example, an SFP), which can be inserted through the opening 11. In the partial cutaway view of FIG. 1B, dummy protective inserts 13 are inserted into the openings 11 in place of connectors to protect the cages 6 while they are not in use. In some examples, the cage may be for receiving an optical transceiver. In some examples, the signal connector is an optical connector.

The cage 6 is configured to guide a connector towards the rear of the cage by the main body. The cage 6 may define an internal space or bore, having a cross section that complements the cross section of the connector, so as to guide the connector accurately to an interface 8 that is positioned within the cage 6. When the connector is fully inserted in the cage 6, the connector mates with the interface 8. This allows signals to pass from the connector to the PCB 4 via the interface 8, or from the PCB 4 to the connector via the interface 8.

The cage body 7 provides an open area 17, e.g. on a top side of the cage 6. In some examples, the open area 17 is a majority part of the top side of the cage 6. The open area 17 is an aperture in the cage 6 through which a coupling member according to some embodiments is configured to extend. In the conventional example shown in FIG. 1A, a SFP heat sink 18 is located over the open area 17. On top of the SFP heat sink 18, a thermal pad 19 is attached. The thermal pad is arranged to put the SFP heat sink in thermal connection with a main unit heat sink 25 (FIG. 1B). A dedicated spring, or clip, 20 is used to hold the SFP heat sink in place. The main unit heat sink may be manufactured from a material having a high thermal conductivity, and may include one or more fins 27 or other features designed to dissipate heat. As shown in FIG. 1B, the fins 27 may extend in a direction parallel to the longitudinal direction of the openings 11. That is, the fins 27 may extend in the same direction in which a connector is inserted into the openings 11.

Aspects of the present disclosure recognise that thermal management for optical components, e.g. a DWDM SFP, can be improved on standard open frame cages on which are anchored a heat sink through a dedicated spring/clip. The heat sink must be kept in position with a dedicated spring and so requires a manual operation for assembly of the unit. The thickness of the solution limits the height available for other components, e.g. heat dissipating fins on the main heat sink. The interface module may be suitable for use in a computerized or processing apparatus, such as a networked computer, server or a network node for a telecommunications network.

For example, FIG. 2 is a schematic diagram of a conventional arrangement of an SFP cage 6 of an interface module 1, a PCB 4 and a heat sink 25 including heat sink fins 27. The SFP cage 6 contacts main unit heat sink 25 through an SFP heat sink 18 and a thermal pad 19. The SFP heat sink 18 and the thermal pad 19 provide a thermal path to allow heat to flow from the SFP cage 6 to the main unit heat sink 25, but also provide some thermal resistance to heat flow therebetween. Moreover, the SFP heat sink 18 and the thermal pad 19 take up significant space within the thickness of the main unit, which is constrained due to the available space within a rack in which it is configured to be mounted (e.g., 1 rack unit, or RU).

Aspects of the present disclosure provide for modified components providing for thermal dissipation of heat from a connector (e.g. SFP) to a heat sink of the interface module.

The conventional arrangement illustrated in FIGS. 1A, 1B and 2 may have certain drawbacks. For example, the conventional arrangement includes two heat sinks (i.e., a main unit heat sink and an SFP heat sink) connected with a thermal pad. This arrangement may increase thermal resistance, which can reduce heat dissipation. In addition, the conventional arrangement requires many different components to be used, since the SFP heat sink must be kept in position with a dedicated spring. The large number of components increases manufacturing cost and complexity.

Moreover, the thickness of the conventional arrangement may limit the height of the main heat sink fin (since the maximum allowed dimension is 1 RU). With a lower height fin, the thermal management of the system is worsened, and more powerful fan trays may be required. However, that has the drawback of increasing of the overall unit power consumption and noise.

Some embodiments described herein may address one or more of the issues with conventional arrangements by providing a new cage design that includes an integrated thermal coupling member for providing a thermal connection to a main unit heat sink. An integrated thermal coupling member according to some embodiments transfers heat from the SFP cage to the main unit heat sink without the need for an SFP heat sink and/or a thermal pad.

In particular, some embodiments provide an interface module including an SFP cage having an opening in a first side thereof (in some examples referred to as a first surface). The SFP cage extends in a longitudinal direction corresponding to the direction in which a connector is to be inserted into the SFP cage. A corrugated thermal coupling member is attached or integral to the SFP cage and extends across the opening. The corrugated thermal coupling member comprises a plurality of alternating ridges and valleys that alternatingly extend above and below the first side of the SFP cage. The plurality of alternating ridges and valleys may be arranged to extend in a direction that is transverse to the longitudinal direction.

In some embodiments, an outer side of the plurality of ridges is configured to contact the main unit heat sink when it is affixed to the interface module, and an inner side of the plurality of valleys is configured to contact a connector when it is inserted into the SFP cage, where “outer” and “inner” are relative to the interior volume of the SFP cage. Thus, when a connector is inserted into the RFP cage, the thermal coupling member is compressed from both outer and inner sides, thereby providing a physical connection and thermal pathway between the connector and the main unit heat sink. This may ensure thermal contact without the need of the thermal pad and/or RFP heat sink.

In some embodiments, an outer side of the plurality of ridges is configured to contact the printed circuit board (PCB) when the SFP cage is mounted to the PCB. Thus, when the RFP cage is mounted to the PCB, the thermal coupling member is compressed from both outer and inner sides, thereby providing a physical connection and thermal pathway between the connector and the PCB. Such an arrangement may exploit the PCB (with ground layer) to sink heat. Moreover, such an arrangement may provide a better ground contact between the SFP module and the cage, which may improve electromagnetic interference shielding performance of the SFP cage.

By eliminating the need for a thermal pad and/or RFP heat sink, the manufacturing complexity and/or manufacturing cost of the interface unit may be reduced, and the thermal performance of the system may be improved. Improved thermal performance may enable the use of higher power SFP28 modules and/or may allow the use of less powerful and/or less noisy fan trays. In particular, improved thermal performance may be obtained due to lower thermal resistance between the SFP cage and the main unit heat sink.

Additionally, eliminating the SFP heat sink and/or the thermal pad may enable the main unit heat sink to have longer fins, which may improve the thermal performance of the main unit heat sink.

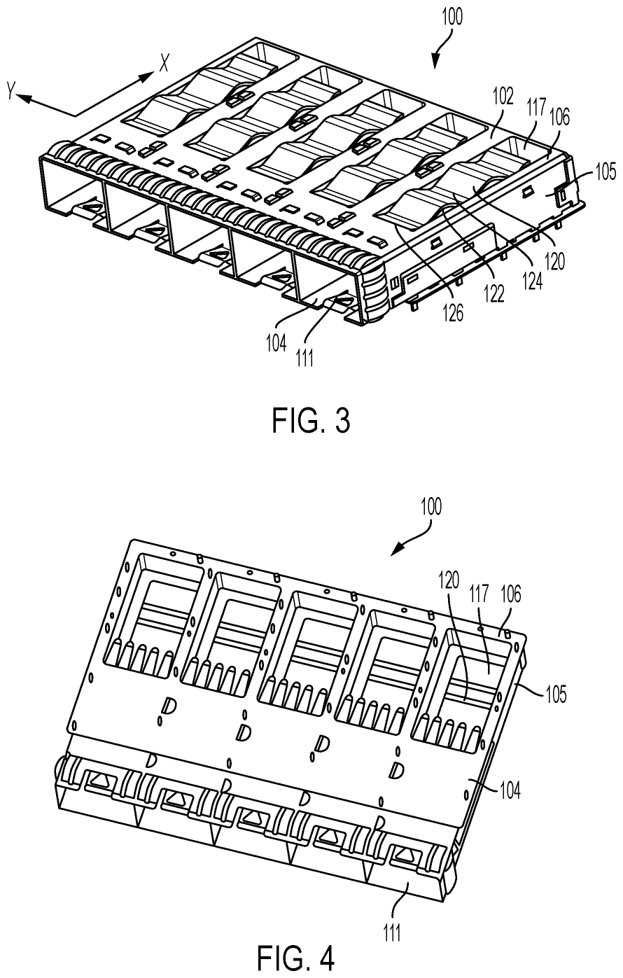

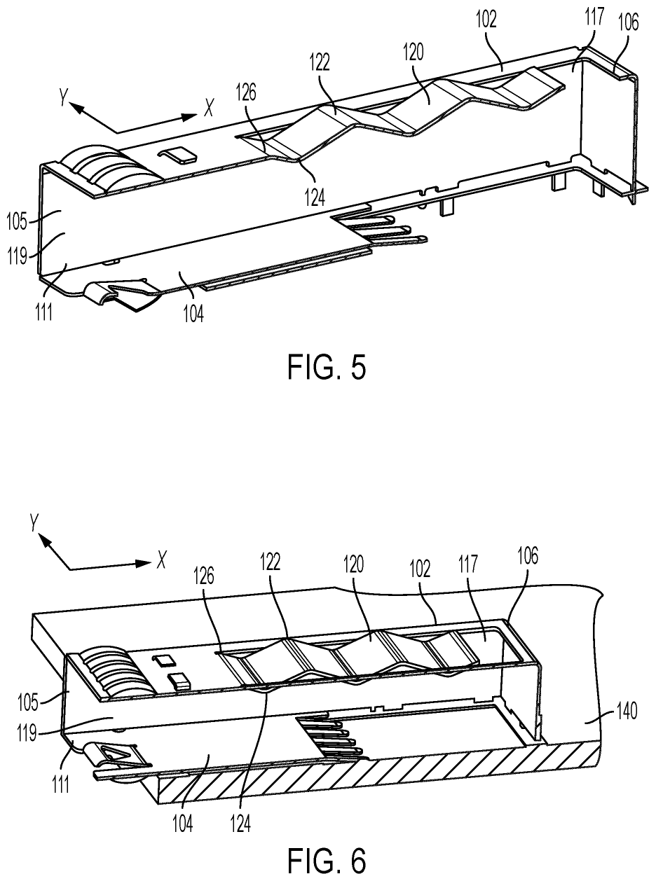

A cage set 100 for an interface unit according to some embodiments is illustrated in FIGS. 3 to 6, in which FIG. 3 is an upper perspective view and FIG. 4 is a lower perspective view of the cage set 100. FIG. 5 is an upper perspective cutaway view of one cage 6 of the cage set 100 alone, while FIG. 6 is an upper perspective cutaway view of one cage 6 of the cage set 100 mounted on a PCB 104.

Referring to FIGS. 3 to 6, a cage set 100 according to some embodiments includes a plurality of SFP cages 106, each of which has an opening 111 in a front end thereof for receiving a signal connector (not shown). The SFP cages 106 may be referred to as a set of SFP cages 106. The unit, or cage set 100, may comprise one or more sets of SFP cages 106.

Each SFP cage 106 includes a first (top) side 102 and a second (bottom) side 104 that are spaced apart by a pair of opposing sidewalls 105. An opening 117 is formed in the first side 102 of the SFP cage 106 through which the signal connector can contact a main unit heat sink, as discussed in more detail below.

Each SFP cage 106 extends in a longitudinal (X) direction corresponding to the direction in which a signal connector is to be inserted into the SFP cage 106. A thermal coupling member 120 is attached, for example, attached as an integral part of the SFP cage 106 at an attachment location 126 adjacent the opening 117. The thermal coupling member 120 extends across the opening 117, e.g. in a cantilevered manner. The thermal coupling member 120 has a corrugated structure. In some examples, the thermal coupling member 120 comprises a plurality of alternating ridges 122 and valleys 124. In some examples, the ridges 122 and valleys 124 extend alternatingly above and below the first side 102 of the SFP cage 106 and into and out of the interior volume 119 defined by the first side 102, the second side 104 and the sidewalls 105 of the SFP cage 106.

The thermal coupler 120 is configured to deform upon insertion of the signal connector into the SFP cage 106. Before installation of the interface unit 100 in a main unit, the ridges 122 extend above the first side 102 of the SFP cage 106 outside the interior volume 119 of the SFP cage 106, while the valleys 124 extend below the first side 102 of the SFP cage inside the interior volume 119 of the SFP cage 106.

The plurality of alternating ridges 122 and valleys 124 may extend in a transverse Y-direction that is perpendicular to the longitudinal X-direction, so that a signal connector inserted into the SFP cage will engage the bottom surface of the thermal coupling member 120 at multiple locations corresponding to the valleys 124. An upper side of the thermal coupling member 120 is configured to contact the main unit heat sink when it is affixed to the cage set 100 at multiple locations corresponding to the peaks 122.

Each thermal coupler 120 is movable with respect to the SFP cage 106. In the illustrated embodiment, the thermal coupler 120 comprises a plate that is separated from the SFP cage 106 along three edges thereof. At these three edges (e.g. two side edges and a third edge that is distal to the SFP cage body opening 111), the floating portion is not coupled to the SFP cage 106. At an edge 126 closest to the opening 111, the thermal coupler 120 is coupled to the SFP cage 106, such that the thermal coupler 120 acts as a flap and is able to move up and down relative to the SFP cage 106 body, i.e. into and out of the interior volume 119 of the SFP cage 106 for receiving the signal connector.

In some examples, the SFP cage 106 and thermal coupler 120 are integrally formed. In some examples, a plane of the thermal coupler 120 is parallel to the plane of the top surface 102 of the SFP cage 106. The floating portion is corrugated such that the valleys 124 extend into the interior volume 119 defined by the SFP cage body. This provides for an inserted signal connector to contact the thermal coupling member 120, and push the thermal coupler 120 towards the unit heat sink.

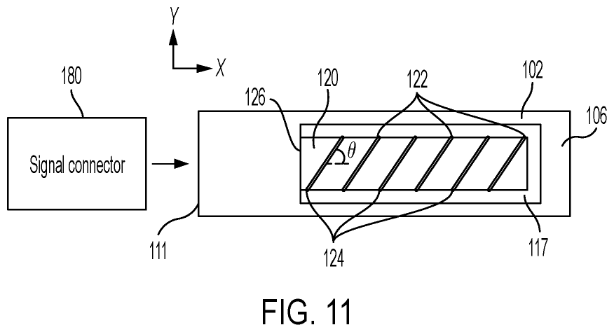

The ridges 122 and valleys 124 of the thermal coupler 120 are formed as linear bends in the thermal coupler that are arranged in parallel with one another in the Y-direction as shown in FIGS. 3 to 6. In the illustrated embodiments, the ridges 122 and valleys 124 are arranged to be transverse to the longitudinal (X-direction) in which a signal connector is inserted into the SFP cage 106. However, in some embodiments, the ridges 122 and valleys 124 may be arranged to be oblique or parallel to the longitudinal (X-direction). For example, brief reference is made to FIG. 11, which is a plan view of an SFP cage 106. The top surface 102 of the SFP cage 106 includes an opening 117 across which extends a thermal coupling member 120 having a plurality of alternating ridges 122 and valleys 124. The ridges and valleys 122, 124 are arranged to be oblique to the longitudinal (X) direction along which the signal connector 180 is inserted. In particular, the ridges and valleys 122, 124 are arranged at an angle θ relative to the longitudinal (X) direction that is less than 90 degrees. In some embodiments, the angle θ may be about 60 to 80 degrees, and in some embodiments, the angle θ may be about 70 degrees.

In some examples, the SFP cage 106 and thermal coupling member 120 are formed from the same sheet of material (e.g., steel, aluminum, copper, etc.), and the ridges 122 and valleys 124 may be created by bending the sheet of material.

Referring again to FIG. 6, the cage set 100 is mounted to a PCB 140 so that the second (bottom) side 104 of each SFP cage 106 contacts the PCB 140 and the first (top) side of each SFP cage 106 faces away from the PCB 140.

Although the opening 117 and corrugated thermal coupling member 120 are illustrated in FIGS. 3 to 6 as being formed in the first side 102 of the SFP cage 106, it will be appreciated that an opening 117 and corrugated thermal coupling member 120 may be provided in any side of the SFP Cage 106, including the bottom side 104 and/or the sidewalls 105 of the SFP cage 106. In particular, in some embodiments, an opening 117 may be formed in a sidewall 105, and a corrugated thermal coupling member 120 may be provided in the opening 117 in the sidewall 105 to contact a heatsink or other thermally conductive member provided adjacent the cage set 100. In some embodiments, an opening 117 may be formed in the bottom side 104, and a corrugated thermal coupling member 120 may be provided in the opening 117 in the lower side 104 to contact a PCB adjacent the cage set 100.

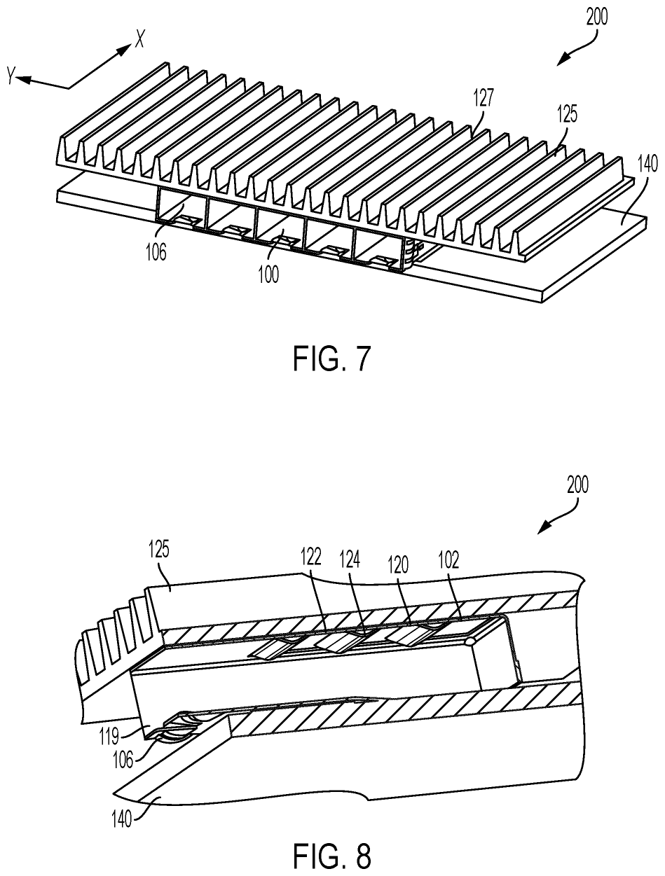

FIGS. 7 and 8 illustrate an interface module 200 including a cage set 100 that is mounted to a PCB 140 and on which a main unit heat sink 125 is attached. The cage set 100 includes a plurality of SFP cages 106 that are sandwiched between the PCB 140 and the main unit heat sink 125 such that the main unit heat sink 125 directly contacts a plurality of the SFP cages 106. The main unit heat sink 125 includes a plurality of heat sink fins 127. In some embodiments, the heat sink fins 127 extend in the longitudinal (X) direction corresponding to the direction of orientation of the SFP cages 106.

As best seen in FIG. 8, which is a partial cutaway view of a single SFP cage 106 between the PCB 140 and the main unit heat sink 125, an outer surface of the thermal coupling member 120 contacts the main unit heat sink 125 at the ridges 122 when it is affixed to the cage set 100. This may cause the thermal coupling member 120 to partially deform, causing the thermal coupling member 120 to contact the main unit heat sink 125 across a larger surface area than just the ridges 122 and provide a spring bias against the main unit heat sink 125. This deformation creates a larger contact surface between the SFP cage 106 and the main unit heat sink 125, which reduces thermal resistance between the SFP cage 106 and the main unit heat sink 125.

Still referring to FIG. 8, while the ridges 122 of the thermal coupling member 120 may be deformed by contact with the main unit heat sink 125, the valleys 124 of the thermal coupling member 120 still extend into the interior volume 119 of the SFP cage 106 before insertion of a signal connector into the SFP cage 106. When a signal connector is inserted into the interior volume 119 of the SFP cage 106, an outer surface of the signal connector will contact the inner surface of the thermal coupling member 120 at the valleys, which may cause the thermal coupling member 120 to partially deform to contact the signal connector over a larger surface area than just at the valleys 124 and provide a spring bias against the signal connector. An inserted signal connector thereby becomes firmly mechanically secured within the SFP cage 106 with a short thermal path between the signal connector and the main unit heat sink 125 provided by the thermal coupling member 120. Accordingly, when the signal connector is inserted into the SFP cage 106, the thermal coupling member 120 applies a spring bias against both the signal connector and the main unit heat sink 125, resulting in a reliable and continuous thermal connection between the signal connector and the main unit heat sink 125.

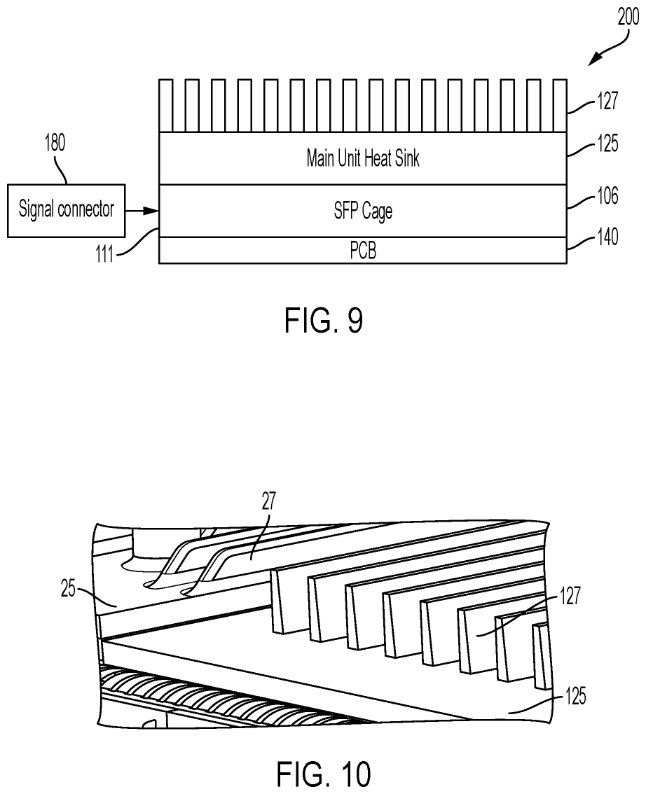

FIG. 9 is a schematic diagram of an arrangement of an interface module 200 according to some embodiments including an SFP cage 106 mounted to a PCB 140 and a heat sink 125 including heat sink fins 127. A signal connector 180 is insertable into the SFP cage 106 though the opening 111. It will be appreciated that the illustration of heat sink fins 127 in FIG. 9 is schematic, and that the heat sink fins 127 may extend parallel to the direction of insertion of the signal connector 180.

The SFP cage 106 contacts the main unit heat sink 25 directly rather than through an SFP heat sink and thermal pad as in the conventional approach. This may reduce the overall thickness of the structure and/or may provide a shorter, more efficient thermal path for heat to flow from the SFP cage 106 to the main unit heat sink 125. Moreover, due to the reduction in thickness of the components, the heat sink fins 127 of the main unit heat sink 125 may be made longer than otherwise possible, which may increase the surface area of the fins 127 and thereby improve the thermal performance of the main unit heat sink 125 in removing heat from the system.

For example, FIG. 10 is a comparison structure showing the heat sink fins 127 of a main unit heat sink 125 structure according to some embodiments next to conventional heat sink fins 27 of a main unit heat sink 25 of a conventional structure. In some cases, the height of the main unit heat sink fins 127 may be increased as much as 50% or more relative to conventional heat sink fins 25. For example, in one implementation, the height of the main unit heat sink fins may be increased from 4.2 mm to 6.35 mm.

Some embodiments may allow keeping the optical transceiver density on the front of a unit, even with higher power consumption connectors (e.g. transceivers or SFP) without increasing the unit thickness. As such, the unit can stay within 1 rack unit. Moreover, some embodiments may allow the main unit heat sink to be larger that it would otherwise be, i.e. heat sink fin height increase. An improved thermal performance makes possible the use of higher power connectors (e.g. SFP28) and could allow the use of less powerful and less noisy fan trays also on existing units.

Some embodiments may further avoid the use of the traditional connector (e.g. SFP) custom/standard heat sink with an associated spring, so less components may be required with consistent thickness reduction, as well as a reduction in assembly labor.

Some embodiments may provide for the thickness of the solution be smaller and allow to increase the height of the main heat sink fin increasing the allowing the use of less powerful fan trays with savings on the overall unit power consumption and noise.

Those skilled in the art will appreciate that the precise dimensions of the connector system described above, as well as the materials used, etc, may be varied so as to provide an optimal compromise between ease of use and thermal transfer efficiency.

In some examples, the interface module 100 is for a computing apparatus (e.g. a computer, or server). In other embodiments, the apparatus may be any device that receives or transmits input or output signals (whether electric signals or optical signals), and thus has need of an input/output connector system. For example, the apparatus may be a node within a telecommunications network or radio access network, e.g. at a base station. In some examples, the apparatus comprises one or more, e.g. a plurality, of interface modules as described. The interface module provides one or more input/output connections to external devices or network components, via a cable assembly. Thus signals received via the interface module can be passed to a processor circuitry of the apparatus, e.g. for demodulation, and/or the processor circuitry can generate and transmit signals via the interface module.

Embodiments of the disclosure thus provide an efficient mechanism for the dissipation of heat in an input/output connector system.

Aspects of the device relates to thermal management of optical transceivers for telecom equipment for Radio Access Networks, for example in fronthaul devices or backhaul devices, or any other node comprising optical transceivers.

The above disclosure sets forth specific details, such as particular embodiments or examples for purposes of explanation and not limitation. It will be appreciated by one skilled in the art that other examples may be employed apart from these specific details.

1. An interface module, comprising:
a cage configured to guide a signal connector towards an interface for connection with the signal connector, wherein the cage comprises:
a first side,
an opening in the first side of the cage, and
a corrugated thermal coupling member attached to the cage and extending across the opening in the first side of the cage, wherein the corrugated thermal coupling member comprises a plurality of alternating ridges and valleys.

2. The interface module of claim 1, wherein the cage has an interior volume defined by the first side, a second side opposite the first side, and sidewalls extending between the first side and the second side; and wherein the corrugated thermal coupling member alternatingly extends into and out of the interior volume.

3. The interface module of claim 1, wherein the cage is configured to guide the signal connector along a longitudinal direction when the signal connector is inserted into the cage, and wherein the plurality of ridges and valleys of the corrugated thermal coupling member extend in a transverse direction that is perpendicular to the longitudinal direction.

4. The interface module of claim 1, wherein an outer side of the plurality of ridges is configured to contact a main unit heat sink when the main unit heat sink is affixed to the interface module.

5. The interface module of claim 4, wherein the corrugated thermal coupling member is configured be deformed by contact with the main unit heat sink when the main unit heat sink is affixed to the interface module.

6. The interface module of claim 1, wherein an outer side of the plurality of ridges is configured to contact a printed circuit board, PCB, when the interface module is affixed to the PCB.

7. (canceled)

8. The interface module of claim 1, wherein the cage comprises a second side configured to be affixed to a main unit heat sink and a third side, opposite the second side, configured to be affixed to a printed circuit board, PCB, wherein the first side comprises a sidewall that extends between the second side and the third side.

9-10. (canceled)

11. The interface module of claim 1, further comprising a printed circuit board (PCB) and a main unit heat sink, wherein the cage is mounted to the PCB on a second side of the cage opposite the first side of the cage, and wherein the main unit heat sink is directly in contact with the first side of the cage.

12. The interface module of claim 1, wherein the corrugated thermal coupling member is attached to the cage at an edge of the opening in the first side of the cage near a first end of the cage at which the signal connector is inserted.

13. The interface module according to claim 1, wherein the ridges and valleys are arranged at an angle that is oblique to a direction in which the signal connector is inserted in to the cage.

14-19. (canceled)

20. A dense wavelength division multiplexer comprising an interface module 1, wherein the interface module comprises:
a cage configured to guide a signal connector towards an interface for connection with the signal connector, wherein the cage comprises:
a first side,
an opening in the first side of the cage, and
a corrugated thermal coupling member attached to the cage and extending across the opening in the first side of the cage, wherein the corrugated thermal coupling member comprises a plurality of alternating ridges and valleys.

21. A cage set for an interface module, comprising:
a cage configured to guide a signal connector towards an interface for connection with the signal connector, wherein the cage comprises:
a first side
an opening in the first side, and
a corrugated thermal coupling member attached to the cage and extending across the opening, wherein the corrugated thermal coupling member comprises a plurality of alternating ridges and valleys.

22. The cage set of claim 21, wherein the cage 106 has an interior volume defined by the first side, a second side opposite the first side, and sidewalls extending between the first side and the second side;
wherein the corrugated thermal coupling member alternatingly extends into and out of the interior volume.

23. The cage set of claim 21, wherein the cage is configured to guide the signal connector along a longitudinal direction when the signal connector is inserted into the cage, and wherein the plurality of ridges and valleys of the corrugated thermal coupling member extend in a transverse direction that is perpendicular to the longitudinal direction.

24. The cage set of claim 21, wherein an outer side of the plurality of ridges is configured to contact a main unit heat sink when the main unit heat sink is affixed to the interface module.

25. (canceled)

26. The cage set of claim 21, wherein an outer side of the plurality of ridges is configured to contact a printed circuit board, PCB, when the interface module is affixed to the PCB.

27. (canceled)

28. The cage set of claim 21, wherein the cage comprises a second side configured to be affixed to a main unit heat sink and a third side, opposite the second side, configured to be affixed to a printed circuit board, PCB, wherein the first side comprises a sidewall that extends between the second side and the third side.

29. The cage set of claim 21, wherein an inner side of the plurality of valleys is configured to contact the signal connector when the signal connector is inserted into the cage.

30. (canceled)

31. The cage set of claim 21, wherein the corrugated thermal coupling member at least partially protrudes into an internal volume of the cage before the signal connector is inserted into the cage and is pushed outward from the internal volume of the cage when the signal connector is inserted into the cage.

32-33. (canceled)

34. The cage set of claim 21, wherein the corrugated thermal coupling member is attached to the cage at an edge of the opening in the first side of the cage near a first end of the cage at which the signal connector is inserted.

35. The cage set according to claim 21, wherein the ridges and valleys are arranged at an angle that is oblique to a direction in which the signal connector is inserted in to the cage.

36. A dense wavelength division multiplexer comprising a cage set, the cage set comprising:
a cage configured to guide a signal connector towards an interface for connection with the signal connector, wherein the cage comprises:
a first side,
an opening in the first side, and
a corrugated thermal coupling member attached to the cage and extending across the opening, wherein the corrugated thermal coupling member comprises a plurality of alternating ridges and valleys.
